(19) United States
(12) Patent Application Publication
(10) Pub. No.: US 2002/0089890 A1
(43) Pub. Date: Jul. 11, 2002

(54) Memory device and method for accessing a memory

(76) Inventors: Heiko Fibranz, Munchen (DE); Franz-Josef Brucklmayr, Kaufering (DE); Robert Reiner, Neubiberg (DE); Robert Allinger, Unterhaching (DE); Klaus Klosa, Gruningen (CH); Robert Hollfelder, Munchen (DE); Walter Kargl, Graz (AT)

Correspondence Address: LERNER AND GREENBERG, P.A., PATENT ATTORNEYS AND ATTORNEYS AT LAW, Post Office Box 2480, Hollywood, FL, 33020-2480, US

(21) Appl. No.: 10/026,111

(22) Filed: Dec. 24, 2001

Related U.S. Application Data
(63) Continuation of application No. PCT/EP00/04940, filed on May 30, 2000.

(30) Foreign Application Priority Data
Jun. 24, 1999 (DE) 99 112 171.6

(51) Int. Cl. G11C 7/00

(52) U.S. Cl. 365/230.03; 365/200

(57) ABSTRACT

In order to shorten an access time and thus to shorten the entire data processing time, a sector size of a memory device is adapted to respective applications. Each application is assigned a respective sector. The access right is checked only once for each application.

### CROSS-REFERENCE TO RELATED APPLICATION

This application is a continuation of copending International Application PCT/EP00/04940, filed May 30, 2000, which designated the United States.

### BACKGROUND OF THE INVENTION

### FIELD OF THE INVENTION

The invention relates to a method for accessing a memory having sectors, wherein a number of rows form a sector and wherein a number of keys are provided for the memory. The invention furthermore relates to a memory device having a memory with a plurality of sectors and a plurality of keys.

Credit cards, telephone cards, insurance or identity cards, to name just a few examples of a number of so-called machine-readable smart cards, are equipped with a data memory in which, in part, highly sensitive data are stored, which must be protected against unauthorized access. In order to protect highly sensitive data, there are usually a plurality of keys stored on the smart card. Prior to processing the data stored in the memory of the smart card, for example reading, writing, erasing or changing, a computation operation is performed to ascertain, both on the smart card and in the read/write device, whether the read/write device is authorized to do this. Thus, by way of example, keys are provided which provide authorization for read-only, for reading and writing of data or for debiting, crediting and debiting of values.

The memory of a smart card according to the prior art is divided into sectors of equal size, each sector being allocated two keys. However, applications often require more than one sector, so that each sector associated with an application must also be assigned at least one key.

Since, in such cases, the access right is therefore checked anew for each sector during the processing of the data within an application, the data processing time is disadvantageously increased.

FIG. 2 shows a known memory SP according to the prior art with n sectors S1 to Sn; each of the sectors S1 to Sn includes three rows Z1 to Z3. Each sector is assigned one or more keys A1, B1 to An, Bn; each key provides authorization for an access right.

By way of example, if the sectors S1 and S2 include an application, for example debiting from an account, then the sector S2 is assigned the same keys as the sector S1. Whenever access is made from one sector to the other, that is to say from the sector S1 to the sector S2 or vice versa, the access right is checked anew, as a result of which the access time and hence the entire data processing time is increased. Since the sectors are not always fully utilized in the case of relatively small applications, existing memory locations are not utilized and so they are actually superfluous.

### SUMMARY OF THE INVENTION

It is accordingly an object of the invention to provide a method for accessing a memory which overcomes the above-mentioned disadvantages of the heretofore-known methods of this general type and which significantly shortens the data processing time and optimizes the utilization of the memory. A further object of the invention is to provide a memory device which can be used with the method according to the invention.

With the foregoing and other objects in view there is provided, in accordance with the invention, a method for accessing a memory, the method includes the steps of:

providing a memory including a plurality of rows, a respective number of the rows forming a respective sector;

providing, for each application, at least one sector having a variable sector size;

assigning an application-specific sector code to a sector;

providing a plurality of keys;

assigning at least one access right and a key link number to a key; and

assigning at least one key link number to an application-specific sector code such that rights are assigned to a corresponding sector.

In other words, the object of the invention is achieved by virtue of the fact that, for each application, one sector, or alternatively, if appropriate, a plurality of sectors, with variable sector size is or are provided.

With the objects of the invention in view there is also provided, a memory device, including:

a memory including a plurality of rows and a plurality of sectors, a respective number of the rows forming a respective one of the sectors;

each of the sectors having an application-specific size;

each of the sectors being provided with a respective application-specific sector code, at least one key link number being assigned to the respective application-specific sector code such that rights are assigned to a corresponding segment of the memory; and

a plurality of keys, each of the keys being assigned at least one access right and a key link number, each of the keys being provided with at least one code, the at least one code authorizing a respective one of the keys only for access to a given one of the sectors determined by a corresponding application-specific code.

In other words, the object of the invention with regard to the memory device is achieved by virtue of the fact that each of the sectors has an application-specific size, that each sector is provided with an application-specific code, and that each key is likewise provided with a code which authorizes the key only for accessing a sector which is determined by the corresponding application-specific code.

According to another feature of the invention, the memory is configured to store a signature for each unit formed from a key, a code for the key and an associated access right, and the memory is configured such that the signature is checked during authentication for protection against manipulations.

According to another feature of the invention, the memory is configured to store, for each of the sectors, a respective signature to be checked during each data access.

According to another feature of the invention, the memory is configured to store a signature containing a chip serial number.

According to another feature of the invention, the keys are provided in respective ones of the rows and the sectors.

A second way of achieving the object of the invention provides for a row to be assigned one or more access rights and one or more linkages, via which the row may be assigned one or more keys, for rows with and without keys to be provided, and for all rows with the same linkage to form a virtual sector.

Accordingly, with the objects of the invention in view there is also provided, a method for accessing a memory, the method includes the steps of:

providing a memory including a plurality of rows, a respective number of the rows forming a respective sector;

providing a plurality of keys;

assigning at least one access right and at least one linkage to a row, the at least one linkage being usable for assigning at least one key to a row;

providing some of the rows with keys and providing some of the rows without keys; and

forming a virtual sector with rows having a same linkage.

Another mode of the invention includes the step of assigning at least one access right to a key link number.

A further mode of the invention includes the step of assigning at least one access right to a row link number.

Yet another mode of the invention includes the step of assigning at least one application-specific sector code to a sector.

Another mode of the invention includes the step of assigning at least one key code to a key allowing access only to sectors with a corresponding sector code.

A further mode of the invention includes the step of assigning at least one access right to a key code.

Another mode of the invention includes the step of assigning at least one access right to a sector code.

In contrast to the known memory organization on a smart card, according to the invention the size of the sectors is not identical, but rather can be adapted to the respective application.

In one embodiment of the invention, a memory is divided into a plurality of sectors which are constructed from individual rows. The number of rows of a sector is chosen in a manner dependent on the application. Each row is assigned at least one row link number. Rows associated with the same application have the same row link number. In order to organize the access according to access rights, a plurality of keys are provided. In a similar manner to how each row is assigned a row link number, each key is assigned a key link number. The key link number of a key corresponds to the row link number of that row or rows which is or are assigned to the key. A key only has access to those rows whose row link number corresponds to its key link number.

By virtue of the measure of adapting the sector size to the respective application, only one key is required for each application and hence for each sector, whereas in the prior art each sector of the same application is assigned a key. In the case of the invention, therefore, the access right is checked only once during the implementation of each application, whereas it is checked anew for each sector in the case of the prior art. The method according to the invention therefore achieves an acceleration of the data processing and utilizes the memory optimally.

A third exemplary embodiment of the invention provides for a signature to be provided for each unit including key, key link number and associated access right. These signatures are stored in the memory SP and checked during authentication.

Another mode of the invention includes the steps of storing, in the memory, a signature for each unit formed of a key, a key code and an associated access right; and checking the signature stored in the memory during authentication for protection against manipulations.

A further exemplary embodiment provides for rows having the same row link numbers to he assigned a signature which is likewise stored in the memory SP and checked during each access.

The signatures may, for example, contain the serial number of the chip in addition to further data.

In order to give individual rows of a sector different access authorizations, provision is made for assigning a plurality of row link numbers to a row. Each key whose key link number corresponds to one of the numbers of a row therefore has access to this row.

The application-specific code of a sector corresponds to the link number of the sector or the rows thereof. The key code corresponds to the key link number in a similar manner. Therefore, a key only allows access to a sector whose applications-specific code is assigned to the code of the key.

In a further exemplary embodiment, a signature is provided for each unit including key, code of the key and associated access right. These signatures are stored in the memory and checked during authentication.

In accordance with a further exemplary embodiment of the invention, each sector is assigned a signature which is likewise stored in the memory and checked during each access. Further exemplary embodiments of the invention include the measures presented below.

For rows having the same row link numbers or for sectors, a signature is stored in the memory, which signature is checked during each data access.

As has already been mentioned earlier above, the signatures may, for example, contain the serial number of the chip in addition to further data.

A key link number or a row link number may be assigned one or more access rights. In a similar manner, a key code or a sector code may be assigned one or more access rights. The key code of a key only allows access to sectors with a corresponding sector code.

A row may also be assigned a plurality of row link numbers.

Further exemplary embodiments and refinements of the invention are provided by the following measures.

A successful authentication with a key allows all accesses in accordance with the access rights assigned to the key link numbers or the key codes. An access in accordance with an access right to a sector or a row is possible only when one of the sector codes or one of the row link numbers corresponds to one of the key link numbers or key codes of the keys which have been successfully authenticated. In a similar manner, an access in accordance with an access right to a sector or a row is possible only when all keys whose key link numbers or key codes correspond to the row link numbers or sector codes assigned to the respective access rights have been successfully authenticated.

Furthermore, provision may be made for providing the keys in rows or sectors which are managed by access rights. By way of example, a read right may be required in order to allow an authentication with a key. It is also possible to provide a particular right for authentication in order to allow an authentication with a key. However, this does not preclude the fact that it is also possible for rows or sectors to be provided which require no authentication for specific types of access.

Analogously to the authentication, a particular access right may be provided for the free access. A free access may be regulated through the use of a particular row link number or a particular sector code. Finally, it is also possible to provide a particular key in order to regulate a free access.

Another mode of the invention includes the step of assigning a key pair to rows having keys.

Another mode of the invention includes the step of providing the key pair as a pair of keys of equal authorization.

A further mode of the invention includes the step of providing the keys as keys that are authenticated by themselves or via other keys.

Another mode of the invention includes the step of providing the key pair as a pair of hierarchically ordered keys.

Other features which are considered as characteristic for the invention are set forth in the appended claims.

Exemplary embodiments of a memory organization according to the invention will now be described and explained with reference to the drawings. Although the invention is illustrated and described herein as embodied in method for accessing a memory and a corresponding memory device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram illustrating an exemplary memory organization according to the invention;

FIG. 2 is a block diagram illustrating a memory organization according to the prior art; and

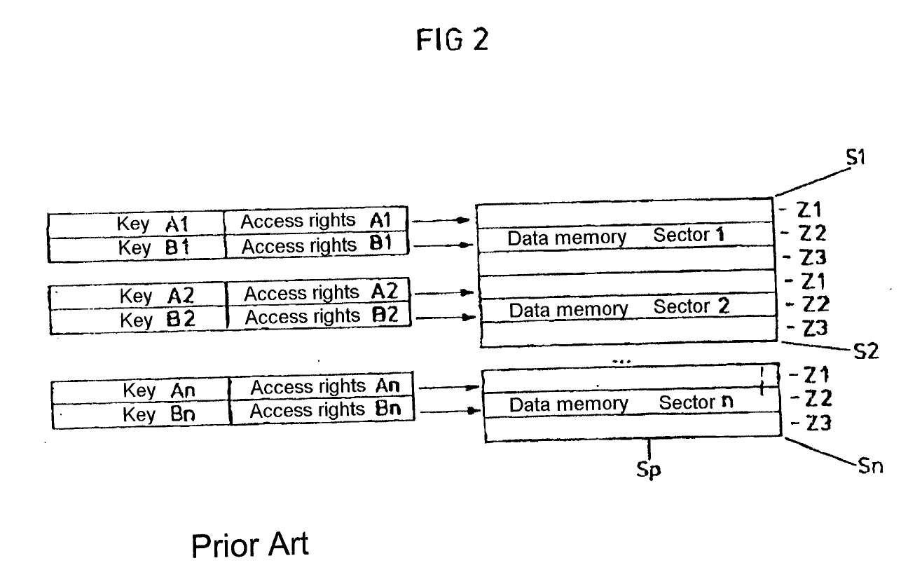

FIG. 3 is a block diagram illustrating an exemplary memory organization according to a further embodiment of the invention.

### DESCRIPTION OF THE PREFERRED EMBODIMENTS

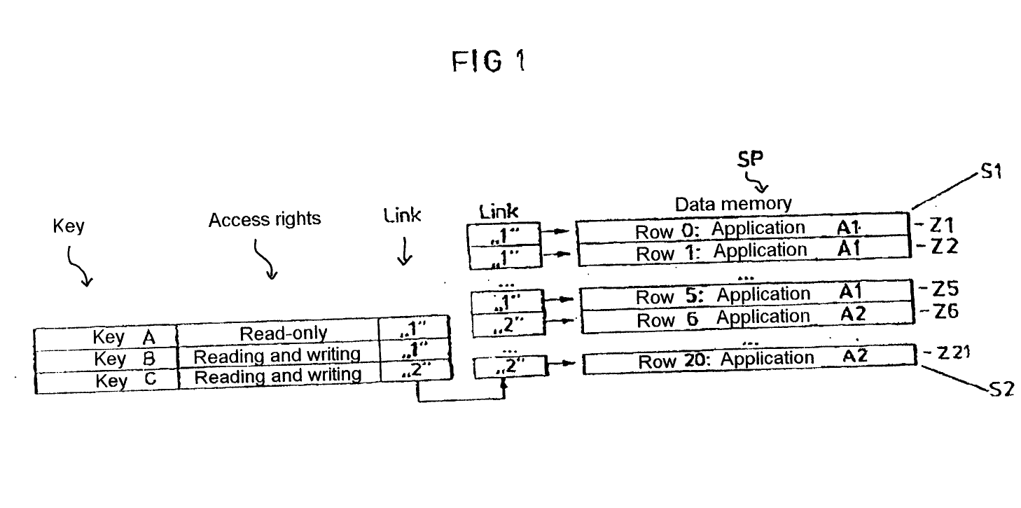

Referring now to the figures of the drawings in detail and first, particularly, to FIG. 1 thereof, there is shown an exemplary memory organization according to the invention. In this memory organization two applications are integrated on the smart card, an application A1, which relates for example to the debiting of values, and an application A2, which relates for example to the crediting of values. The application A1 requires six rows Z1 to Z6, which are combined to form a sector S1, while the application A2 requires 15 rows Z7 to Z21, which are combined to form a sector S2. Three keys A, B, C are provided. The key A provides authorization for read-only; the keys B and C provide authorization for reading and writing. The key A and the key B belong to the application A1; they both have the key link number 1. The rows of the sector S1 all have the same number, namely 1, which corresponds to the key link number of the key A and of the key B. All rows of the sector S2 have the number 2, which is assigned to the key C. Therefore, all rows with the row link number 1 can be read with the key A. With the key B, all rows with the number 1 can be read and also be written to. With the key C, all rows with the row link number 2 can be read and be written to. By contrast, the rows with the row link number 2 cannot be accessed with the keys A and B. Equally, the rows with the row link number 1 cannot be accessed with the key C.

By virtue of the measure according to the invention, namely to adapt the sector size to the individual applications, only one check of the access right per application is necessary, whereas, as already mentioned, in the prior art as many checks are necessary as an application occupies sectors.

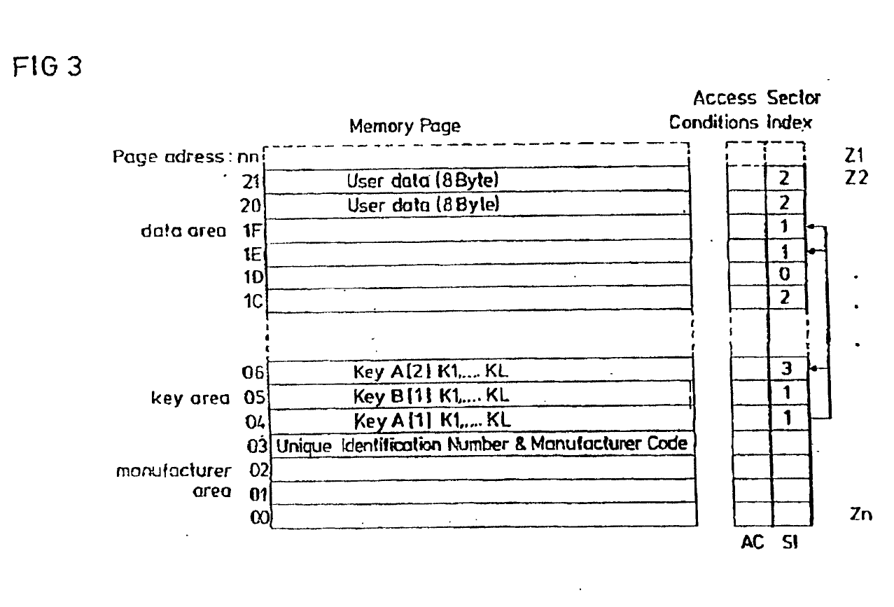

An exemplary embodiment of the method which is shown in FIG. 3 will now be described and explained.

The memory configuration represented in FIG. 3 is largely configured flexibly. The memory is subdivided into n rows each having eight bytes, for example, which are initially not assigned to any segment. However, each of these rows has an additional sector index register SI and also a configuration register AC, for which only two bytes are additionally required. Through the use of the sector index SI, a row is assigned the keys K1 to Kk required for authentication. A row may be assigned one key or alternatively a plurality of keys. A preferred refinement of the invention provides for a key pair to be provided for each row. The two keys of the key pair may have equal authorization or be ordered hierarchically. In the case of the hierarchical key concept, the access rights of an individual key can be set individually in the configuration register AC of the row. The keys themselves can also again be authenticated through the use of other keys or by themselves and be read or written in accordance with the access rights held in the configuration register. All rows with the same sector index are associated with the same application and form a virtual sector.

One advantage of this concept is that each application key only has to be stored once irrespective of the size of the application. The size and number of the segments is freely selectable. The number of defined segments determines the number of key pairs required, so that the remaining memory space is entirely available for application data.

The invention is particularly suitable for use on a smart card. However, the invention is not restricted to this one application, because it can advantageously be used wherever the access to memory locations is regulated by access rights.

We claim:

1. A method for accessing a memory, the method which comprises:
providing a memory including a plurality of rows, a respective number of the rows forming a respective sector;
providing, for each application, at least one sector having a variable sector size;
assigning an application-specific sector code to a sector;
providing a plurality of keys;
assigning at least one access right and a key link number to a key; and
assigning at least one key link number to an application-specific sector code such that rights are assigned to a corresponding sector.

2. The method according to claim 1, which comprises:
assigning at least one row link number to a row such that rows which are assigned to a same sector bear a same row link number;
assigning a respective key link number to each key such that a key link number of a key corresponds to a row link number of at least one row whose sector is assigned to the key; and
ensuring that a key allows access only to rows whose row link number corresponds to the key link number.

3. The method according to claim 2, which comprises assigning at least one access right to a key link number.

4. The method according to claim 2, which comprises assigning at least one access right to a row link number.

5. The method according to claim 17 which comprises assigning at least one application-specific sector code to a sector.

6. The method according to claim 5, which comprises assigning at least one key code to a key allowing access only to sectors with a corresponding sector code.

7. The method according to claim 6, which comprises assigning at least one access right to a key code.

8. The method according to claim 6, which comprises assigning at least one access right to a sector code.

9. The method according to claim 2, which comprises:
storing, in the memory, a signature for each unit formed of a key, a key link number and an associated access right; and
checking the signature stored in the memory during authentication for protection against manipulations.

10. The method according to claim 6, which comprises:
storing, in the memory, a signature for each unit formed of a key, a key code and an associated access right; and
checking the signature stored in the memory during authentication for protection against manipulations.

11. The method according to claim 2, which comprises:
storing, in the memory, a signature for rows having a same row link number; and
checking the signature during each data access.

12. The method according to claim 1, which comprises:
storing, in the memory, a signature for each sector; and
checking the signature during each data access.

13. The method according to claim 2, which comprises:
storing, in the memory, a signature containing a chip serial number; and
checking the signature during each data access.

14. The method according to claim 2, which comprises assigning a plurality of row link numbers to a row.

15. The method according to claim 2, which comprises:
storing, in the memory, a signature for each unit formed of a key, an access right and one of a key link number and a key code;
checking the signature stored in the memory during authentication for protection against manipulations; and
allowing all accesses in accordance with the access right assigned to the one of the key link number and the key code upon a successful authentication with the key.

16. The method according to claim 2, which comprises:
storing, in the memory, a signature for each unit formed of a key, an access right and one of a key link number and a key code;
checking the signature stored in the memory during authentication for protection against manipulations; and
allowing an access in accordance with an access right to one of a sector and a row only if one of a sector code and a row link number corresponds to one of a key link number and a key code of a successfully authenticated key.

17. The method according to claim 2, which comprises:
storing, in the memory, a signature for each unit formed of a key, an access right and one of a key link number and a key code;
checking the signature stored in the memory during authentication for protection against manipulations; and
allowing an access in accordance with an access right to one of a sector and a row only when all keys that have one of key link numbers and key codes corresponding to one of row link numbers and sector codes assigned to respective access rights have been successfully authenticated.

18. The method according to claim 1, which comprises providing the keys in one of rows and sectors managed by access rights.

19. The method according to claim 18, which comprises requiring a read right in order to allow an authentication with a key.

20. The method according to claim 18, which comprises requiring a particular right for authentication in order to allow an authentication with a key.

21. The method according to claim 1, which comprises providing one of given rows and given sectors requiring no authentication for specific types of access.

22. The method according to claim 21, which comprises requiring a particular access right for a free access.

23. The method according to claim 21, which comprises allowing a free access via one of a particular row link number and a particular sector code.

24. The method according to claim 21, which comprises regulating a free access by using a particular key.

25. A method for accessing a memory, the method which comprises:
providing a memory including a plurality of rows, a respective number of the rows forming a respective sector;
providing a plurality of keys;
assigning at least one access right and at least one linkage to a row, the at least one linkage being usable for assigning at least one key to a row;
providing some of the rows with keys and providing some of the rows without keys; and
forming a virtual sector with rows having a same linkage.

26. The method according to claim 25, which comprises assigning at least one key code to a key allowing access only to sectors with a corresponding sector code.

27. The method according to claim 26, which comprises assigning at least one access right to a key code.

28. The method according to claim 26, which comprises assigning at least one access right to a sector code.

29. The method according to claim 26, which comprises:
storing, in the memory, a signature for each unit formed of a key, a key code and an associated access right; and
checking the signature stored in the memory during authentication for protection against manipulations.

30. The method according to claim 25, which comprises:
storing, in the memory, a signature for each sector; and
checking the signature during each data access.

31. The method according to claim 26, which comprises:
storing, in the memory, a signature containing a chip serial number; and
checking the signature during each data access.

32. The method according to claim 26, which comprises assigning a plurality of row link numbers to a row.

33. The method according to claim 26, which comprises:
storing, in the memory, a signature for each unit formed of a key, an access right and one of a key link number and a key code;
checking the signature stored in the memory during authentication for protection against manipulations; and
allowing all accesses in accordance with the access right assigned to the one of the key link number and the key code upon a successful authentication with the key.

34. The method according to claim 26, which comprises:
storing, in the memory, a signature for each unit formed of a key, an access right and one of a key link number and a key code;
checking the signature stored in the memory during authentication for protection against manipulations; and
allowing an access in accordance with an access right to one of a sector and a row only if one of a sector code and a row link number corresponds to one of a key link number and a key code of a successfully authenticated key.

35. The method according to claim 26, which comprises:
storing, in the memory, a signature for each unit formed of a key, an access right and one of a key link number and a key code;
checking the signature stored in the memory during authentication for protection against manipulations; and
allowing an access in accordance with an access right to one of a sector and a row only when all keys that have one of key link numbers and key codes corresponding to one of row link numbers and sector codes assigned to respective access rights have been successfully authenticated.

36. The method according to claim 25, which comprises providing the keys in one of rows and sectors managed by access rights.

37. The method according to claim 36, which comprises requiring a read right in order to allow an authentication with a key.

38. The method according to claim 36, which comprises requiring a particular right for authentication in order to allow an authentication with a key.

39. The method according to claim 25, which comprises providing one of given rows and given sectors requiring no authentication for specific types of access.

40. The method according to claim 39, which comprises requiring a particular access right for a free access.

41. The method according to claim 39, which comprises allowing a free access via one of a particular row link number and a particular sector code.

42. The method according to claim 39, which comprises regulating a free access by using a particular key.

43. The method according to claim 26, which comprises assigning a key pair to rows having keys.

44. The method according to claim 43, which comprises providing the key pair as a pair of keys of equal authorization.

45. The method according to claim 43, which comprises providing the key pair as a pair of hierarchically ordered keys.

46. The method according to claim 25, which comprises providing the keys as keys that are authenticated by themselves.

47. The method according to claim 25, which comprises providing the keys as keys that are authenticated with other keys.

48. A memory device, comprising:
a memory including a plurality of rows and a plurality of sectors, a respective number of said rows forming a respective one of said sectors;
each of said sectors having an application-specific size;
each of said sectors being provided with a respective application-specific sector code, at least one key link number being assigned to the respective application-specific sector code such that rights are assigned to a corresponding segment of said memory; and
a plurality of keys, each of said keys being assigned at least one access right and a key link number, each of said keys being provided with at least one code, the at least one code authorizing a respective one of said keys only for access to a given one of said sectors determined by a corresponding application-specific code.

49. The memory device according to claim 48, wherein said memory is configured to store a signature for each unit formed from a key, a code for said key and an associated access right, and said memory is configured such that said signature is checked during authentication for protection against manipulations.

50. The memory device according to claim 48, wherein said memory is configured to store, for each of said sectors, a respective signature to be checked during each data access.

51. The memory device according to claim 48, wherein said memory is configured to store a signature containing a chip serial number.

52. The memory device according to claim 48, wherein said keys are provided in respective ones of said rows and said sectors.
